(19) United States
(12) Patent Application Publication
(10) Pub. No.: US 2021/0090946 A1
(43) Pub. Date: Mar. 25, 2021

(54) MULTIPLE LAYER COPPER SEEDING

(71) Applicant: Intel Corporation, Santa Clara, CA (US)

(72) Inventors: Darko GRUJICIC, Chandler, AZ (US); Matthew ANDERSON, Chandler, AZ (US); Adrian BAYRAKTAROGLU, Chandler, AZ (US); Roy DITTLER, Chandler, AZ (US); Benjamin DUONG, Chandler, AZ (US); Tarek A. IBRAHIM, Mesa, AZ (US); Rahul N. MANEPALLI, Chandler, AZ (US); Suddhasattwa NAD, Chandler, AZ (US); Rengarajan SHANMUGAM, Chandler, AZ (US); Marcel WALL, Phoenix, AZ (US)

(21) Appl. No.: 16/578,698

(22) Filed: Sep. 23, 2019

(51) Int. Cl. H01L 21/768; H01L 23/522; H01L 23/532

(52) U.S. Cl. CPC H01L 21/76871; H01L 23/53228; H01L 23/5226

(57) ABSTRACT

Embodiments herein relate to systems, apparatuses, and/or processes directed to a package or a manufacturing process flow for creating a package that uses multiple seeding techniques to fill vias in the package. Embodiments include a first layer of copper seeding coupled with a portion of the boundary surface and a second layer of copper seeding coupled with the boundary surface or the first layer of copper seeding, where the first layer of copper seeding and the second layer of copper seeding have a combined thickness along the boundary surface that is greater than a threshold value.

### FIELD

Embodiments of the present disclosure generally relate to the field of package assemblies, and in particular package assemblies that include copper vias.

### BACKGROUND

Continued reduction in end product size of mobile electronic devices such as smart phones and ultrabooks is a driving force for the development of reduced size and increased complexity and density system-in-package components.

### BRIEF DESCRIPTION OF THE DRAWINGS

FIGS. 1A-1C illustrate an example of a package assembly using multiple seeding layers at various stages of a manufacturing process, in accordance with embodiments.

FIGS. 2A-2C illustrate another example of a package assembly using multiple seeding layers at various stages of a manufacturing process, in accordance with embodiments.

FIGS. 3A-3C illustrate another example of a package assembly using multiple seeding layers at various stages of a manufacturing process, in accordance with embodiments.

FIGS. 4A-4B illustrate an example of a package assembly using multiple seeding layers applied with reverse biases at various stages of a manufacturing process, in accordance with embodiments.

FIG. 5 illustrates an example of a process for using multiple seeding layers for a package assembly, in accordance with embodiments.

FIG. 6 schematically illustrates a computing system, in accordance with embodiments of the present invention.

### DETAILED DESCRIPTION

Embodiments of the present disclosure may generally relate to systems, apparatus, and/or processes directed to a package or a manufacturing process flow for creating a package that uses multiple seeding techniques to fill vias, for example for eventual plating, in the package. Embodiments may be directed to a copper layer of a package having a first side and a second side opposite the first side, where the second side of the copper layer is coupled with a side of a substrate. Embodiments include one or more buildup layers that are coupled with the first side of the copper layer, where at least a portion of one or more sides of the one or more buildup layers and at least a portion of the first side of the copper layer define a boundary surface for an opening, where the opening is to be at least partially filled with copper. Embodiments include a first layer of copper seeding coupled with a portion of the boundary surface and a second layer of copper seeding coupled with the boundary surface or the first layer of copper seeding, where the first layer of copper seeding and the second layer of copper seeding have a combined thickness along the boundary surface that is greater than a threshold value. In other embodiments, the opening may be a via within a package.

With respect to package manufacture, semi-additive processing (SAP) involves stacking alternate layers of buildup dielectrics and patterned copper interconnects to create a substrate package that routes multifunctional silicon dies to external circuity. Heterogeneous architectures that drive miniaturization and higher functionality such as on-die-interconnect (ODI) architectures, embedded multi-die interconnect bridge (EMIB®) architectures, fan-out architectures, and other architectures will increasingly be used for high performance computing, cloud computing, client computing segment, mobile sector devices, internet-of-things implementations, automotive sector solutions, wearable and/or flexible electronics, and the like.

Legacy SAP substrate packaging involves lamination, laser drilling to create vias, metallization, and patterning (e.g. plating and etching) that result in interconnect features (e.g. traces, vias, etc.) to create internal 3D circuitry. Via features may be drilled into buildup dielectrics, provide for connectivity between top layers to mid-level metal layers (e.g. blind vias), and also enable 2.5 or 3D architecture features such as through silicon vias (TSVs).

During manufacture, drilled via features may use seed layer deposition on insulating dielectrics so that they can be subsequently filled in with copper (e.g. by an electrolytic process) to achieve through-via electrical continuity. Seed layer deposition may be carried out by electroless plating that involves multiple wet chemical processing steps. Sputtering is an alternative dry physical deposition technique used for seed layer deposition.

In legacy implementations, electroless seeding has been used for two-sided buildup for traditional architectures, and frequently used for high volume manufacturing (HVM) scale manufacturing. Sputtering process could be used for seed deposition for heterogeneous architectures such as ODI that may require a one-sided buildup.

For one-sided glass heterogeneous architectures, as well as other architectures, the laser via drilling process ablates polymeric resin that may leave behind residue and/or debris on the copper pad of the package. Subsequent via residue removal, even using a mild etching process, inadvertently creates an undercut profile in the dielectric buildup while cleaning the copper pads. This may create a problem for limitations in line-of-sight sputtering and result in poor, non-uniform, or incomplete coverage in difficult-to-reach undercut profiles or side wall undulations. This is especially true for product architectures that include high aspect ratio vias, for example, packages that may be used for high-speed I/O. These limitations may exist when applied to existing architectures as well as for one-sided glass buildup architectures. Nevertheless, the sputtering process otherwise provides a good interfacial adhesion between seed layer and dielectric buildup by making use of special binding layers such as titanium.

Electroless deposition provides relatively uniform seed coverage, even in inaccessible areas such as undercut profiles and high-aspect ratio vias, because it relies on wetting characteristics of liquid phase reactants without line-of-sight limitations. However, for architectures demanding good adhesion on smooth buildup dielectrics (e.g. solder resist (SR) or photoimageable dielectric material (PID) with sub 100 nm roughness), electroless deposition has challenges with activation and seeding coverage. Electroless deposition may also have poor adhesion properties due to the lack of mechanical anchor points. Examples of these challenges may include via patterns created in a very high aspect ratio, and via patterns created using laser or other drilling techniques where via residues left behind from drilling require subsequent pad cleaning within a via, thus creating unintended pad undercuts in the patterned vias.

Achieving a uniform seed layer inside vias is important in SAP process flow in order to provide reliable ohmic contact to the copper pad and to ensure bottom-up filling of the via with electrolytic copper plating without defects. The laser drilling process to create vias may cause ablation of the polymeric dielectric resin leaving behind undesirable residue on the underlying copper pad. Mild etching of these copper pads (typically using wet etchant technology) removes the via residue. However, due to the isotropic etching, undercuts may be formed on the copper pad in both buildup and first level interconnect (FLI) layers.

Electroless process technology is typically utilized for achieving a uniform seed coverage in SAP processing. The undercuts can be sufficiently filled-in by electroless copper process by making use of liquid phase reactions. However, for certain buildup dielectrics, such as solder resist or photoimageable dielectrics, there could be challenges with surface activation, a key step for electroless deposition. Smooth dielectrics also do not provide mechanical anchor sites resulting in poor copper to dielectric adhesion.

Sputter processing provides for an alternate seeding technology, however it is a line-of-sight technique emanating from the sputter target and may not fully deposit a seeding layer in difficult-to-access regions such as via undercuts. A discontinuous seed layer may cause via voiding issues due to lack of electrical continuity for downstream processes and overall impacts the quality of the plated via/bumps.

Embodiments described herein may also be directed to techniques used with packaging architectures having high aspect ratio vias that require adhesion of seed copper to dielectric layer while providing uniform via sidewall coverage. Embodiments may also be directed to techniques used with packaging architectures that require cleaning of laser-created pad debris provide uniform seed deposition in via undercut regions. Embodiments may also be directed to techniques used for one-sided buildup architectures by selective deposition by an electroless process on glass to overcome sputter line-of-sight limitations. Embodiments may also be directed to techniques that include a combination of pad filling, seed bridging, and applying selective electroless plating, and re-sputtering techniques to achieve uniform seed coverage with good adhesion. In embodiments, regular electroless provides a seeding layer on all exposed surfaces, whereas the selective electroless process may seed only on dielectric resin with no seeding on glass.

Embodiments described herein may include first using a sputter technique to deposit seed on buildup or copper in a line-of-sight from the sputter target, encapsulating a majority of the substrate to be seeded. Subsequently, an electroless process may be applied to deposit the remaining seed, to adhere to the sputtered seed or to the other substrate surfaces to achieve a continuous seed layer with no electrical discontinuity for subsequent copper electrolytic plating.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

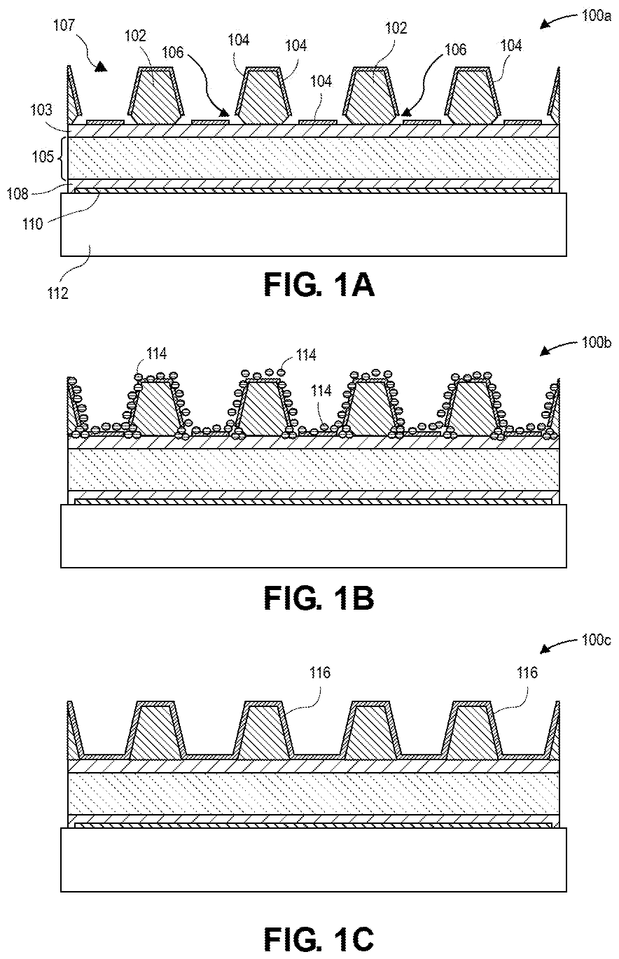

FIGS. 1A-1C illustrate an example of a package assembly using multiple seeding layers at various stages of a manufacturing process, in accordance with embodiments. FIG. 1A includes diagram 100a that shows an example of a package that includes a copper layer 103 onto which via buildups 102 have been coupled. In embodiments, the via buildups 102 may have been created by one or more layers (not shown) of dielectric stacked on each other. Openings 107 are created between the via buildups 102, which may be subsequently filled with copper after a seeding process has been applied as described below.

In embodiments, the openings 107 may be created by a drilling process, which may include use of either a laser drill or mechanical drill, or other techniques. In embodiments, the drilling or other techniques may be similar to those used to create through mold vias (TMVs). In embodiments, the drilling process may result in residue (not shown) coupled with or proximate to the copper layer 103 associated with the openings 107. In embodiments, the copper layer 103 may be one or more copper pads. In embodiments, the openings 107 are cleaned out using an etching process to remove any residue (not shown).

After the cleaning of the openings 107 has been completed, undercuts 106 may exist into the via buildups 102 proximate to the copper layer 103. At this point, sputter deposition process may be used to sputter copper seeding layer 104 onto the top and side surfaces of the via buildups 102 and of areas of the copper layer 103 associated with the openings 107. The sputter deposition process involves ejecting material, for example copper, ballistically in straight lines from a target source (not shown) to portions of the package 100a, resulting in the application of sputtered copper seeding layer 104. The sputter deposition process may be referred to as a dry process and may result in good adhesion to dielectrics and other materials that may be used for the via buildups 102. In addition, adhesion to surfaces that are smooth, or otherwise have a lower level of roughness, is typically high.

However, features within openings 107, such as undercuts 106, that may be out of the line-of-sight of the sputter deposition process may receive little or no sputter material. Other features that may be part of the via buildups 102, which may not be shown in figure 100a, may also cause parts of the via buildups 102 or the copper layer 103 to be obscured and as a result receive little or no sputter material.

As a result, for example, the undercuts 106, may not receive sufficient seed material required for later plating. For successful copper fill of the openings 107, a continuous metal layer is required on all surfaces of the openings 107. Any discontinuity in the seed layer may result in a via void defects during downstream copper fill processes that may impact the operation of the package.

FIG. 1B includes diagram 100b that shows an example of a package where an electroless deposition process has been applied to deposit copper seeding layer 114 onto the surface of the package 100b. The electroless copper seeding layer 114 fills in the openings 107 where the sputtered copper seeding layer 104 was unable to be deposited, such as undercuts 106 of FIG. 1A. As a result, as shown in diagram 100c of FIG. 1C, a layer of copper seeding 116 may be distributed uniformly as a result of the sputtered copper seeding layer 104 and the electroless copper seeding layer 114.

The electroless deposition process is a wet chemical process that does not rely on line-of-sight from a sputtering target. As a result, the electroless deposition process may bring electroless copper seeding layer 114 to all exposed areas of package 100b. However, the adhesive properties of the electroless deposition process is less than the sputtering deposition process. Because a majority of the seeding layer may be from sputtered copper seeding layer 104, with electroless copper seeding layer 114 in the undercut 106 locations, the seed layer/dielectric adhesion is positively enhanced by the majority sputtered copper seeding layer 104. In embodiments, the electroless deposition process may be continued until there is even copper seeding 116 coverage as shown in FIG. 1C.

As shown in diagrams 100a, 100b, 100c, the copper layer 103 may be placed on a substrate core 105, that may be coupled with a second copper layer 108, that may be coupled with a bonding layer 110, which may be a temporary bonding film that is photochemically active, to which a glass carrier 112 may be coupled. In embodiments, the glass carrier 112 may be used to provide additional rigidity for the package during manufacture, and may be subsequently be debonded, for example by photo exposing the bonding layer 110.

In embodiments, a modified selective activation on electroless process may be used to get copper adhesion on buildup and none on glass carrier 112. In embodiments, colloidal activation, catalyst masking, and/or sacrificial layers may be used to achieve selectivity to get electroless adhesion on just via buildups 102 or copper layer 103 and not on the glass carrier 112. In embodiments, by not putting seeding layer on glass using selective electroless method, the glass still retains transparency for photo-exposure debonding later on.

A common approach to package manufacture is to have a substrate core, such as core 105, with buildup on both sides with the core 105 in the middle. While this approach has efficiencies, it may introduce warpage issues by using organic stacks (not shown) that may flex. The introduction of a glass carrier 112 allows for tight warpage tolerances (e.g. for silicon die bump interfacing) when using techniques for one-sided package development. These one-sided buildup architectures enable heterogeneous packaging with silicon die interfacing due to tighter warpage tolerances achieved with a glass carrier 112. This approach may require one-sided seeding of a class carrier 112 using a sputtering process. The sputtering process supports good adhesion to ultra-smooth glass carriers 112 via usage of a titanium adhesion layer. However, it has the drawbacks as described above with respect to line-of-sight of the sputter target. Unseeded locations could lead to electrical discontinuity in the seed layer, and during via filling-up (using electroplating) lead to voiding and/or resistivity concerns.

Legacy electroless plating would activate both front, and backsides of the glass carrier 112 during activation/catalysis process, resulting in two-sided plating not suitable for one-sided architectures. Electroless plating may involve using palladium (Pd)-catalyzed or activated redox reactions, with related manufacturing toolsets using panel dipping and/or both-sided spray techniques that would activate both sides of the glass carrier 112, resulting in two-sided plating causing concerns with bonding layer 110 removal. Also, this technique has challenges with good adhesion to glass carriers, and may tend to flake off in a wet plating tanks causing bath stability concerns, and/or inconsistent product quality and yield loss. Thus, the formation of a continuous seed layer is important for enabling one-sided glass-based heterogeneous architectures and existing process flow of electroless plating.

Embodiments may involve using one-sided seed deposition using selective electroless plating to fill in undercut 106, while avoiding electroless copper deposition on the glass carrier 112. This would enable formation of a continuous seed layer that is favorable for downstream processes, and enables manufacture of one-sided glass architectures. Embodiments may use a selectively-activated electroless process to achieve one-sided plating on via buildups 102, with no plating on glass carrier side 112 using colloidal activator, catalyst poisoning, catalyst masking (on glass side), using sacrificial masking layers, and/or combinations thereof.

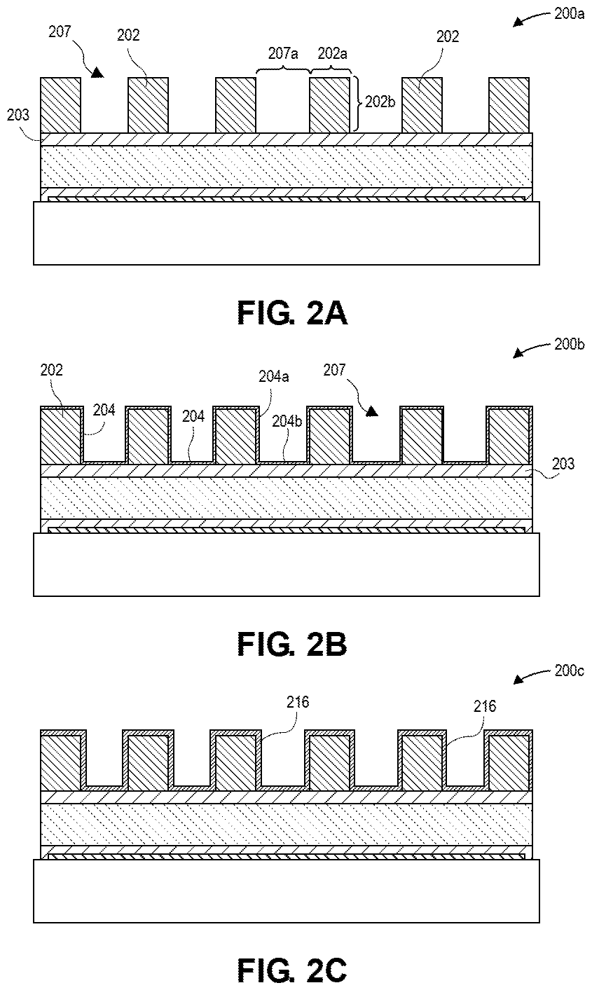

FIGS. 2A-2C illustrate another example of a package assembly using multiple seeding layers at various stages of a manufacturing process, in accordance with embodiments. FIG. 2A includes diagram 200a that shows a package created using a high-resolution process resulting in straight via profiles 202. High-resolution processes are used to incorporate finer pattern features for reduced via size. These finer pattern features will have smaller via dimensions with high aspect ratios. Functional vias (e.g. copper filled) are important for routing electrical signals through these packaging architectures between silicon die and the external circuitry.

As shown, the via profiles 202 may have a high aspect ratio, as measured by ratio of a width 202a and a height 202b of the via profile 202. In addition, the via profiles 202 high aspect ratio may include being positioned close together, with spaces 207 having narrow gaps 207a between the via profiles 202.

FIG. 2B includes diagram 200b that shows a sputtered seed layer 204, which may be similar to sputtered copper seeding layer 104 of FIG. 1A, that has been sputtered from a target (not shown) onto the package 200b. Because the sputtering process relies on line-of-sight, the layer of sputtered seed on the sidewalls 204a of the via profiles 202 may be thinner than the sputtered seed 204b near the copper layer 203, which may be similar to copper layer 103 of FIG. 1A. In addition, side walls of the via profiles 202 may contain undulations (not shown) due to lamination and patterning marginalities which may cause a thinner sputter seed layer. As a result, the sputtered seed on the sidewalls 204a may be of insufficient thickness to provide an adequate seed layer for subsequent copper plating to fill the spaces 207 with copper. The seed thickness variability may cause electrical resistivity differences along the side walls, which creates issues for quality electroplating and subsequent via performance.

FIG. 2C includes diagram 200c that shows a final uniform seed layer 216 resulting from the application of a selective electroless process to deposit additional seed onto the sputtered seed layer 204. The sputtered seed layer 204 may provide good adhesion to the SR of via profiles 202 by utilizing a titanium adhesion layer. The subsequent electroless process activates along the via sidewalls 204a with a lower sputter seeding layer to increase beyond a threshold value. As a result, the final uniform seed layer 216 may have a decreased ohmic resistance for subsequent bump plating. In embodiments, the uniform seed layer 216 meets minimum threshold thickness for electrical performance requirement of the package.

In embodiments of high aspect ratio via profiles 202, the via profiles 202 may be built up using photolithography, a litho drill generates minimal residue on the surface of the copper layer 203 that would require cleaning.

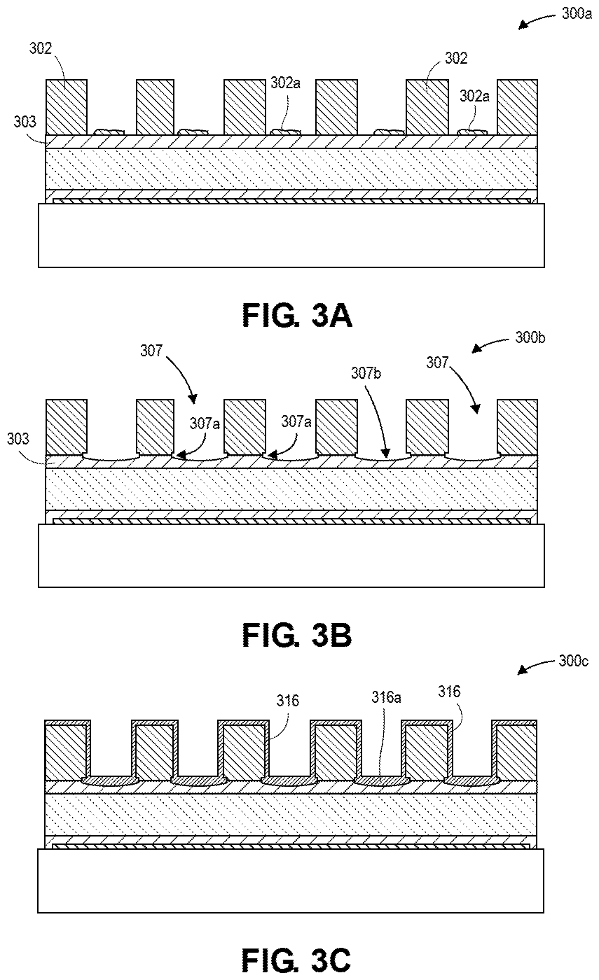

FIGS. 3A-3C illustrate another example of a package assembly using multiple seeding layers at various stages of a manufacturing process, in accordance with embodiments. FIG. 3A includes diagram 300a that shows a via profiles 302, which may be similar to via profiles 202 of FIG. 2A, that uses photodefineable materials that may have resolution capabilities of 2 microns and below.

Defining smaller via features using high-resolution materials may introduce debris 302a on the underlying copper layer 303, and may be similar to copper layer 203 of FIG. 2A. High levels of residue 302a that may require extensive copper layer 303 etching to clean. It is typical to use different pad cleaning techniques in semiconductor substrate process flows to remove the debris as they would interfere with copper filling by seed plating, and electroplating. Different pad cleaning techniques may include mild etching of copper pads to chunk off the debris, attacking the organic debris using specialized desmear chemicals, sonication approaches, copper etch or acidic ultrasonic cleaning, and the like.

FIG. 3B, that includes diagram 300b, shows that an often undesired consequence of pad cleaning is the creation of via undercuts 307a, and pad cavity 307b creation due to isotropic attack of etchant chemicals.

FIG. 3C includes diagram 300c that shows the uniform seed layer 316, which may be similar to uniform seed layer 216 of FIG. 2C, that may include an initial electroless seed deposition 316a used to fill the via undercuts 307a and pad cavities 307b. In embodiments, the package 300b may be immersed in an electroless solution. A sputtering process may then be used to apply additional seeding to the package 300c, which results in the uniform seed layer 316. In embodiments, the uniform seed layer 316 may have a variable thickness, with a minimum thickness above a threshold value.

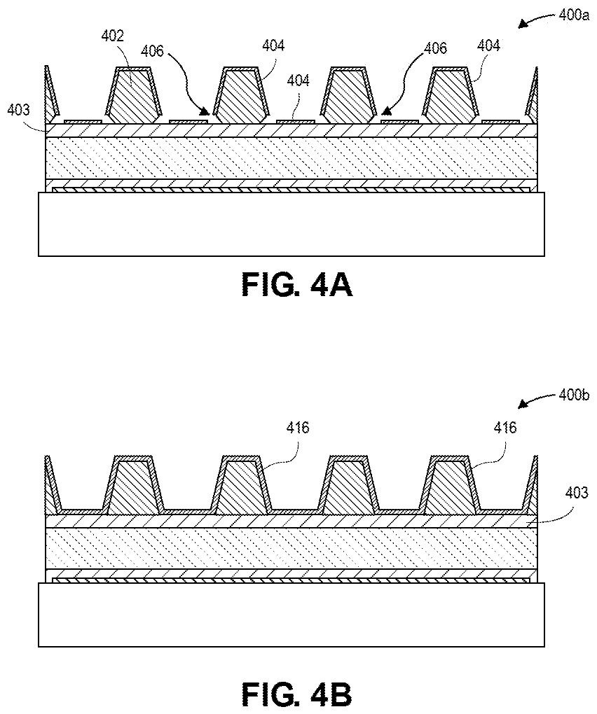

FIGS. 4A-4B illustrate an example of a package assembly using multiple seeding layers applied with reverse biases at various stages of a manufacturing process, in accordance with embodiments. FIG. 4A shows diagram 400a, which shows a package which may be similar to package 100a of FIG. 1A, that includes a sputtered copper seeding layer 404, which may be similar to sputtered copper seeding layer 104 of FIG. 1A, on top of via buildups 402, which may be similar to via buildups 102 of FIG. 1A, and undercuts 406, that may be similar to undercuts 106 of FIG. 1A, that result from an applied etching or cleaning process.

In embodiments, the sputtered copper seeding layer 404 may be applied using a forward bias, but cannot reach the undercuts 406 due to line-of-sight issues as discussed above. After the sputtered copper seeding layer 404 is applied using a forward bias, polarity may be changed to a reverse bias, which may turn the copper layer 403, which may be similar to copper layer 103 of FIG. 1A, into a sputter target that emits copper.

FIG. 4B includes diagram 400b, that shows a uniform copper seed layer 416 where copper from copper layer 403 has filled in the undercuts 406 from diagram 400a due to the change in polarity. The copper layer 403 has turned into a sputter target and has sputtered copper at least into the undercuts 406.

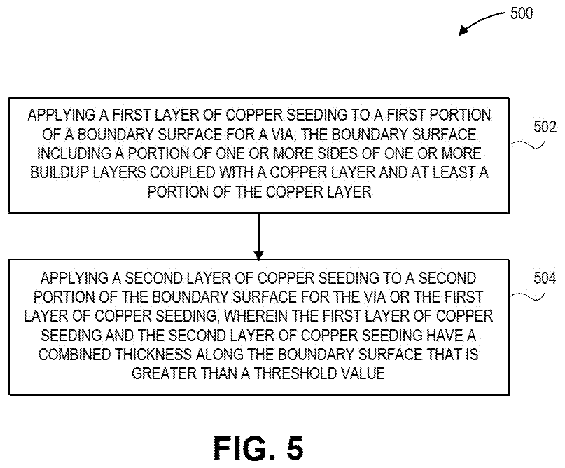

FIG. 5 illustrates an example of a process for using multiple seeding layers for a package assembly, in accordance with embodiments. Diagram 500 shows a process that may be implemented by components or techniques as shown in FIGS. 1A-4B, including in diagrams 100a, 100b, 100c, 200a, 200b, 200c, 300a, 300b, 300c, 400a, and 400b.

At block 502, the process may include applying a first layer of copper seeding to a first portion of a boundary surface for a via, the boundary surface including a portion of one or more sides of one or more buildup layers coupled with a copper layer and at least a portion of the copper layer. In embodiments, the first layer of copper seeding may include copper seeding layer 104 of FIG. 1A applied by a sputter process, copper seeding layer 204, 204a, 204b of FIG. 2A applied by a sputter process, portions of seeding layer 316, 316a of FIG. 3C applied by an electroless process, and copper seeding layer 404 of FIG. 4A applied by an electroless process. The first portion of the boundary surface for a via, including a portion of one or more sides of one or more buildup layers may include the edges of via buildups 102 of FIG. 1A, edges of via profiles 202 and edges 202a, 202b of FIG. 2A, edges of via profiles 302 of FIG. 3A, and via buildups 402 of FIG. 4A. In embodiments, the copper layer and at least a portion of the copper layer may include copper layer 103 of FIG. 1A, copper layer 203 of FIG. 2A, copper layer 303 of FIG. 3A, and copper layer 403 of FIG. 4A.

At block 504, the process may include applying a second layer of copper seeding to a second portion of the boundary surface for the via or the first layer of copper seeding, wherein the first layer of copper seeding and the second layer of copper seeding have a combined thickness along the boundary surface that is greater than a threshold value. In embodiments, the second layer of copper seeding may include copper seeding layer 114 of FIG. 1B applied using an electroless process, portions of seeding layer 216 of FIG. 2C applied using an electroless process, portions of seeding layer 316 of FIG. 3C applied using a sputtering process, and seeding layer 416 of FIG. 4B applied using a reverse bias sputtering process. The first layer of copper seeding in the second layer of copper seeding with a combined thickness that is greater than a threshold value may be found at seeding layer 116 of FIG. 1C, seeding layer 216 of FIG. 2C, seeding layer 316 of FIG. 3C, and seeding layer 416 of FIG. 4B.

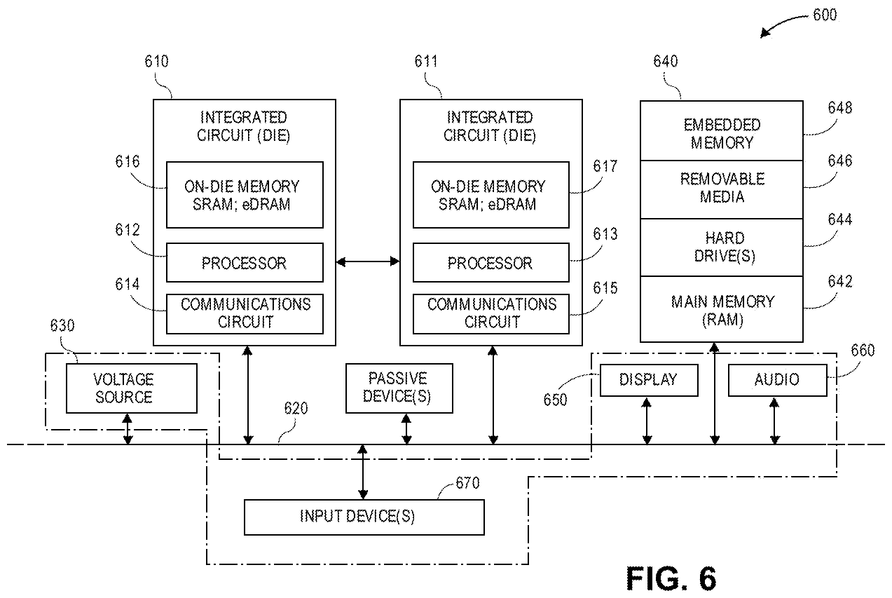

FIG. 6 schematically illustrates a computing system 600, in accordance with embodiments of the present invention. The computer system 600 (also referred to as the electronic system 600) as depicted can embody multiple layer copper seeding, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, multiple layer copper seeding, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having multiple layer copper seeding, according to any of the several disclosed embodiments and their equivalents, an electronic system, a computer system, one or more methods of fabricating an integrated circuit, and one or more methods of fabricating an electronic assembly that includes a package substrate having multiple layer copper seeding, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having multiple layer copper seeding embodiments and their equivalents. A foundation substrate may be included, as represented by the dashed line of FIG. 6. Passive devices may also be included, as is also depicted in FIG. 6.

### EXAMPLES

The following paragraphs describe examples of various embodiments.

Example 1 is a package comprising: a copper layer having a first side and a second side opposite the first side, wherein the second side of the copper layer is coupled with a side of a substrate; one or more buildup layers coupled with the first side of the copper layer; wherein at least a portion of one or more sides of the one or more buildup layers and at least a portion of the first side of the copper layer define a boundary surface for an opening, the opening to be at least partially filled with copper; a first layer of copper seeding coupled with a portion of the boundary surface; and a second layer of copper seeding coupled with the boundary surface or the first layer of copper seeding, wherein the first layer of copper seeding and the second layer of copper seeding have a combined thickness along the boundary surface that is greater than a threshold value.

Example 2 may include the package of example 1, wherein the first layer of copper seeding is applied with a sputtering process.

Example 3 may include the package of example 1, wherein the portion of the boundary surface is a first portion of the boundary surface; further comprising a second portion of the boundary surface that has no first layer of copper seeding or with a first layer of copper seeding that has a thickness below a first layer seeding threshold value.

Example 4 may include the package of example 3, wherein the opening is a via or a high-aspect ratio via.

Example 5 may include the package of example 3, where at least a portion of the second portion of the boundary surface is positioned between one of the one or more buildup layers and the copper layer.

Example 6 may include the package of example 5, where the at least a portion of the second portion of the boundary surface was a result of cleaning of the opening.

Example 7 may include the package of any one of examples 1-6, wherein the second layer of copper seeding is applied with an electroless process.

Example 8 may include the package of example 1, wherein the first layer of copper seeding or the second layer of copper seeding are to fill an etching of the at least a portion of the first side of the copper layer.

Example 9 may include the package of example 1, wherein the first layer of copper seeding is applied with a forward bias; and wherein the second layer of copper seeding is applied with a reverse bias to cause copper to leave the copper layer and form the second layer.

Example 10 is a process for seeding a via, comprising: applying a first layer of copper seeding to a first portion of a boundary surface for a via, the boundary surface including a portion of one or more sides of one or more buildup layers coupled with a copper layer and at least a portion of the copper layer; and applying a second layer of copper seeding to a second portion of the boundary surface for the via or the first layer of copper seeding, wherein the first layer of copper seeding and the second layer of copper seeding have a combined thickness along the boundary surface that is greater than a threshold value.

Example 11 may include the process of example 10, wherein the first layer of copper seeding is applied with a sputtering process.

Example 12 may include the process of example 10, wherein the second layer of copper seeding is applied with an electroless process.

Example 13 may include the process of example 10, wherein the first layer of copper seeding or the second layer of copper seeding are to fill an etching of at least a portion of the copper layer.

Example 14 may include the process of any one of examples 10-13, wherein applying the first layer of copper seeding further includes applying the first layer copper seeding using a forward bias.

Example 15 may include the process of example 14, wherein applying the second layer of copper seeding further includes applying the second layer of copper seeding using a reverse bias.

Example 16 may include the process of example 14, wherein applying the second layer of copper seeding using reverse bias is to cause copper seed to leave the copper layer to form the second layer of copper seed.

Example 17 is a system comprising: a circuit board; a package coupled with the circuit board, the package comprising: a copper layer having a first side and a second side opposite the first side, wherein the second side of the copper layer is coupled with a side of a substrate; one or more buildup layers coupled with the first side of the copper layer; wherein at least a portion of one or more sides of the one or more buildup layers and at least a portion of the first side of the copper layer define a boundary surface for a via, the via to be at least partially filled with copper; a first layer of copper seeding coupled with a portion of the boundary surface; and a second layer of copper seeding coupled with the boundary surface or the first layer of copper seeding, wherein the first layer of copper seeding and the second layer of copper seeding have a combined thickness along the boundary surface that is greater than a threshold value.

Example 18 may include the system of example 17, wherein the first layer of copper seeding is applied with a sputtering process.

Example 19 may include the system of example 17, wherein the second layer of copper seeding is applied with an electroless process.

Example 20 may include the system of any one of example 17-19, wherein the via is a high-aspect ratio via.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a copper layer having a first side and a second side opposite the first side, wherein the second side of the copper layer is coupled with a side of a substrate;
one or more buildup layers coupled with the first side of the copper layer; wherein at least a portion of one or more sides of the one or more buildup layers and at least a portion of the first side of the copper layer define a boundary surface for an opening, the opening to be at least partially filled with copper;
a first layer of copper seeding coupled with a portion of the boundary surface; and
a second layer of copper seeding coupled with the boundary surface or the first layer of copper seeding, wherein the first layer of copper seeding and the second layer of copper seeding have a combined thickness along the boundary surface that is greater than a threshold value.

2. The package of claim 1, wherein the first layer of copper seeding is applied with a sputtering process.

3. The package of claim 1, wherein the portion of the boundary surface is a first portion of the boundary surface;
further comprising a second portion of the boundary surface that has no first layer of copper seeding or with a first layer of copper seeding that has a thickness below a first layer seeding threshold value.

4. The package of claim 3, wherein the opening is a via or a high-aspect ratio via.

5. The package of claim 3, where at least a portion of the second portion of the boundary surface is positioned between one of the one or more buildup layers and the copper layer.

6. The package of claim 5, where the at least a portion of the second portion of the boundary surface was a result of cleaning of the opening.

7. The package of claim 6, wherein the second layer of copper seeding is applied with an electroless process.

8. The package of claim 1, wherein the first layer of copper seeding or the second layer of copper seeding are to fill an etching of the at least a portion of the first side of the copper layer.

9. The package of claim 1, wherein the first layer of copper seeding is applied with a forward bias; and
wherein the second layer of copper seeding is applied with a reverse bias to cause copper to leave the copper layer and form the second layer.

10. A process for seeding a via, comprising:
applying a first layer of copper seeding to a first portion of a boundary surface for a via, the boundary surface including a portion of one or more sides of one or more buildup layers coupled with a copper layer and at least a portion of the copper layer;
applying a second layer of copper seeding to a second portion of the boundary surface for the via or the first layer of copper seeding, wherein the first layer of copper seeding and the second layer of copper seeding have a combined thickness along the boundary surface that is greater than a threshold value.

11. The process of claim 10, wherein the first layer of copper seeding is applied with a sputtering process.

12. The process of claim 10, wherein the second layer of copper seeding is applied with an electroless process.

13. The process of claim 10, wherein the first layer of copper seeding or the second layer of copper seeding are to fill an etching of at least a portion of the copper layer.

14. The process of claim 10, wherein applying the first layer of copper seeding further includes applying the first layer copper seeding using a forward bias.

15. The process of claim 14, wherein applying the second layer of copper seeding further includes applying the second layer of copper seeding using a reverse bias.

16. The process of claim 14, wherein applying the second layer of copper seeding using reverse bias is to cause copper seed to leave the copper layer to form the second layer of copper seed.

17. A system comprising:
a circuit board;
a package coupled with the circuit board, the package comprising:
a copper layer having a first side and a second side opposite the first side, wherein the second side of the copper layer is coupled with a side of a substrate;
one or more buildup layers coupled with the first side of the copper layer; wherein at least a portion of one or more sides of the one or more buildup layers and at least a portion of the first side of the copper layer define a boundary surface for a via, the via to be at least partially filled with copper;
a first layer of copper seeding coupled with a portion of the boundary surface; and
a second layer of copper seeding coupled with the boundary surface or the first layer of copper seeding, wherein the first layer of copper seeding and the second layer of copper seeding have a combined thickness along the boundary surface that is greater than a threshold value.

18. The system of claim 17, wherein the first layer of copper seeding is applied with a sputtering process.

19. The system of claim 17, wherein the second layer of copper seeding is applied with an electroless process.

20. The system of claim 17, wherein the via is a high-aspect ratio via.
